(19) United States
(12) Patent Application Publication
(10) Pub. No.: US 2008/0283833 A1
(43) Pub. Date: Nov. 20, 2008

(54) Thin Film Transistor Array Panel and Manufacturing Method Thereof

(76) Inventors: Bo-Sung Kim, Seoul (KR); Min-Seong Ryu, Gyeonggi-do (KR); Yong-Uk Lee, Gyonggi-do (KR); Tae-Young Choi, Seoul (KR)

Correspondence Address: F. CHAU & ASSOCIATES, LLC, 130 WOODBURY ROAD, WOODBURY, NY, 11797, US

(21) Appl. No.: 10/578,007

(22) PCT Filed: Feb. 7, 2005
(86) PCT No.: PCT/KR05/00380

§ 371 Date: May 2, 2006

(30) Foreign Application Priority Data
Feb. 9, 2004 (KR) 10-2004-0008346

(51) Int. Cl. H01L 27/088

(52) U.S. Cl. 257/59; 257/E27.06

(57) ABSTRACT

The present invention provides a thin film transistor comprising: a substrate (110); a gate electrode (124) formed on the substrate; a gate insulating layer (140) covering the substrate and the gate electrode; a source electrode and a drain electrode (173, 175) formed on the gate insulating layer; a semiconductor layer (150) formed on the gate insulating layer, the source electrode and the drain electrode; and a passivation layer (180) covering the semiconductor layer, the source electrode, the drain electrode and the gate insulating layer, wherein at least one of the gate insulating layer and the passivation layer is made of Parylene.

### BACKGROUND OF THE INVENTION

(a) Field of the Invention

The present disclosure relates to a thin film transistor array panel and a manufacturing method thereof.

(b) Description of the Related Art

A liquid crystal display (LCD) is one of the most widely used flat panel displays. An LCD includes two panels provided with field-generating electrodes, and a liquid crystal (LC) layer interposed between them. The LCD displays images by applying voltages to the field-generating electrodes to generate an electric field in the LC layer, which rearranges orientations of LC molecules in the LC layer to adjust polarization of an incident light.

Recently an LCD includes two panels provided with field-generating electrodes respectively, wherein one panel has a plurality of pixel electrodes in a matrix and the other has a common electrode covering the entire surface of the panel. The LCD can display images by applying a different voltage to each pixel electrode. For this purpose thin film transistors having three terminals to switch voltages applied to pixel electrodes are connected to the pixel electrodes. And gate lines to transmit signals for controlling thin film transistors and data lines to transmit voltages applied to pixel electrodes are formed on a thin film transistor array panel.

Such an LCD panel has a multi-layer structure piling up several conductive layers and insulating layers. Gate lines, data lines, and pixel electrodes are made of different conductive layers (each called a gate electric conductor, a data electric conductor, and a pixel electric conductor) and separated from each other by insulating layers. Generally they are arranged one after another from the bottom layer.

Though glass is generally used as a substrate for an LCD, plastic is used for manufacturing a flexible thin film transistor array panel.

In a manufacturing process of the flexible thin film transistor array panel, chemical vapor deposition (CVD) and baking have a great problem of requiring a high temperature.

Deposition of a nitride film (SiNx) for a gate insulating layer, an amorphous silicon layer, and an organic insulating layer and thermal processes require a high temperature.

Generally, a plastic substrate of a flexible thin film transistor array panel is made of Poly Ether Sulphone (PES), Arylite, and Kaptone as an aligning layer. Though such plastic substrates have high heat resistance, coefficient of thermal expansion (CTE) of them are much different from CTE of silicon (Si).

Accordingly, a stress caused by the difference of CTE between the plastic substrate and the nitride film (SiNx), an amorphous silicon layer, or an organic insulating layer in a high temperature process induces problems such that the substrate is heavily bent or the thin film is easily unfastened.

### SUMMARY OF THE INVENTION

The present invention provides a thin film transistor array panel and a manufacturing method thereof wherein a gate insulating layer and a passivation layer are made of Parylene being deposited in a room temperature.

The present invention provides a thin film transistor array panel comprising: a substrate; a gate electrode formed on the substrate; a gate insulating layer covering the gate electrode and the substrate; a source electrode and a drain electrode formed on the gate insulating layer; a semiconductor layer formed on the gate insulating layer and the source electrode and the drain electrode; and a passivation layer covering the semiconductor layer, the source electrode, the drain electrode, and the gate insulating layer, wherein at least one of the gate insulating layer and the passivation layer is made of Parylene.

The substrate may be made of one material selected from plastic, glass, and metal. The semiconductor layer may be made of an organic semiconductor layer or a silicon semiconductor layer. The thin film transistor array panel further comprises a pixel electrode formed on the passivation layer and connected to the drain electrode through a contact hole of the passivation layer that exposes a portion of the drain electrode.

The present invention provides a manufacturing method of a thin film transistor array panel comprises forming a gate electrode on a substrate; forming a gate insulating layer covering the gate electrode on the substrate; forming a source electrode and a drain electrode on the gate insulating layer; forming a semiconductor layer covering the source electrode and a portion of the drain electrode; and forming a passivation layer covering the gate insulating layer, the source electrode, the drain electrode, and the semiconductor layer, wherein at least one of the gate insulating layer and the passivation layer is made of Parylene.

Here, the gate insulating layer and the passivation layer may be made of Parylene by chemical vapor deposition.

The present invention provides a thin film transistor comprising: a substrate; a gate electrode formed on the substrate; a gate insulating layer covering the substrate and the gate electrode; a semiconductor layer formed on the gate insulating layer and disposed on the corresponding portion of the gate electrode; a source electrode and a drain electrode contacting portions of the semiconductor layer, formed on the gate insulating layer, and separated by a predetermined distance; and a passivation layer covering the semiconductor layer, the gate insulating layer, the source electrode, and the drain electrode, wherein at least one of the gate insulating layer and the passivation layer is made of Parylene.

The present invention provides a thin film transistor array panel comprising: a substrate; a source electrode and a drain electrode formed on the substrate and separated by a predetermined distance; a semiconductor layer covering the source electrode and the drain electrode; a gate insulating layer covering the substrate and the semiconductor layer; a gate electrode formed on the gate insulating layer and disposed on the corresponding portion between the source electrode and the drain electrode; and a passivation layer covering the gate insulating layer and the gate electrode, wherein at least one of the gate insulating layer and the passivation layer is made of Parylene.

The thin film transistor may further comprise a pixel electrode formed on the passivation layer and connected to the drain electrode through a contact hole of the gate insulating layer and the passivation layer that exposes a portion of the drain electrode.

### BRIEF DESCRIPTION OF THE DRAWINGS

FIG. 1 is a layout view of a thin film transistor array panel according to a first to third embodiments of the present invention;

FIG. 2 is a sectional view of the thin film transistor array panel according to a first embodiment of the present invention shown in FIG. 1 taken along the line II-II′;

FIGS. 3A to 3E are sectional views illustrating sequential steps of a manufacturing method of a thin film transistor array panel according to the first embodiment of the present invention;

FIG. 4 is a sectional view of the thin film transistor array panel according to a second embodiment of the present invention shown in FIG. 1 taken along the line II-II′; and

FIG. 5 is a sectional view of the thin film transistor array panel according to a third embodiment of the present invention shown in FIG. 1 taken along the line II-II′.

### DETAILED DESCRIPTION OF THE PREFERRED EMBODIMENTS

Preferred embodiments of the present invention now will be described more fully hereinafter with reference to the accompanying drawings, in which preferred embodiments of the invention are shown. The present invention may, however, be embodied in different forms and should not be construed as being limited to the embodiments set forth herein.

In the drawings, the thickness of layers, films, and regions are exaggerated for clarity. Like numerals refer to like elements throughout. It will be understood that when an element such as a layer, film, region, or substrate is referred to as being “on” another element, it can be directly on the other element or intervening elements may also be present. By contrast, it will be understood that when an element such as a layer, film, region, or substrate is referred to as being “directly on” another element, it means that intervening elements must not be present.

Henceforth, a structure of a thin film transistor array panel and a manufacturing method thereof according to embodiments of the present invention will be described in detail with reference to accompanying drawings.

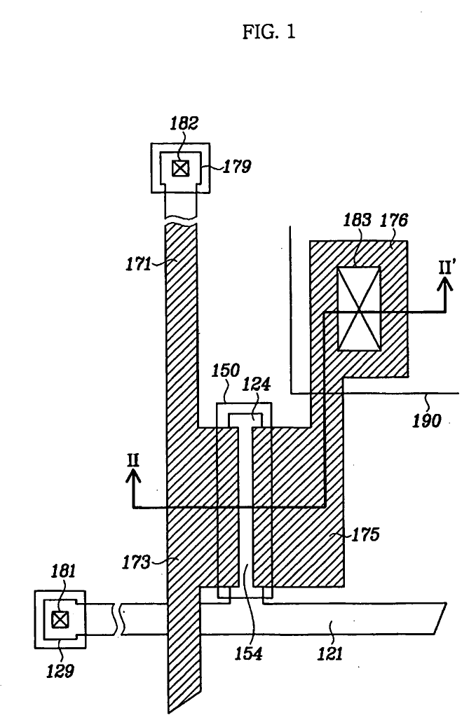

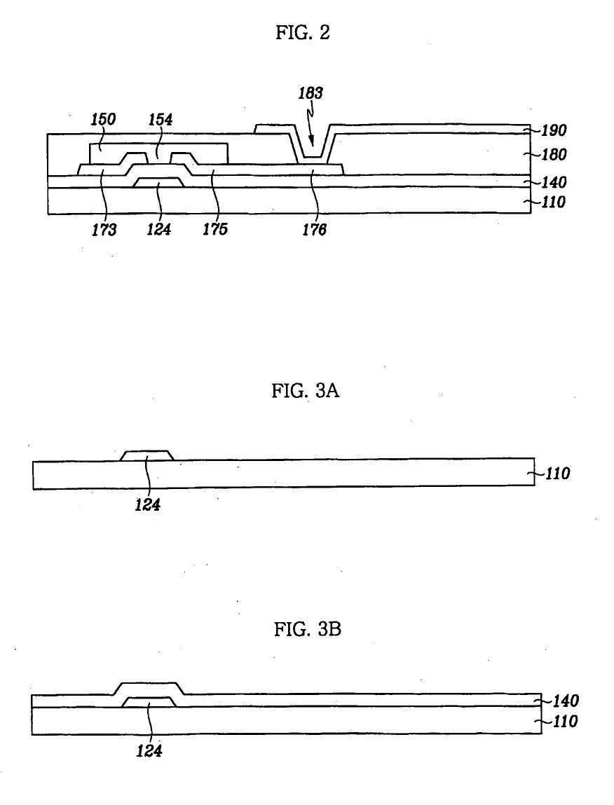

FIG. 1 is a layout view of a thin film transistor array panel according to a first to third embodiment of the present invention and FIG. 2 is a sectional view of the thin film diode array panel according to a first embodiment of the present invention shown in FIG. 1 taken along the line II-II′.

As shown in FIG. 1 and FIG. 2, metal wiring paths of gate lines 121, 124, and 129 are formed on a substrate 110 in a thin film transistor array panel according to a first embodiment of the present invention. The substrate 110 may be made of plastic, glass, or metal. A thin film transistor array panel according to a first embodiment of the present invention will be described on the basis of a plastic substrate.

A gate line 121 transmitting a gate signal is extending in a traverse direction. A plurality of gate electrodes 124 consist of upward or downward salient portions of the gate line 121. The width of the one end 129 of the gate line 121 is enlarged for contacting with and receiving a scanning signal from an external circuit.

The gate line 121 includes a conductive layer made of silver (Ag) series such as silver or silver alloys or aluminum (Al) series such as aluminum or aluminum alloys. The gate line 121 may have a multi-layer structure further including other conductive layers made of other materials specially such as chrome (Cr), titanium (Ti), tantalum (Ta), molybdenum (Mo), and their alloys (for example molybdenum-tungsten (MoW) alloys) having a good physical, chemical, and electric contact properties with indium tin oxide (ITO) or indium zinc oxide (IZO). A good combination of a lower layer and an upper layer is chrome/aluminum-neodymium (Cr/Al—Nd) alloys.

The edge surfaces of the gate lines 121 are tapered, and the inclination angle of the edge surfaces with respect to a surface of the substrate 110 is in a range of about 30-80 degrees.

A gate insulating layer 140 made of Parylene is formed on the gate line 121.

Parylene as the abbreviation for poly-para-xylylene are polymers formed by chemical vapor deposition (CVD) in a vacuum.

Such structures of Parylene polymers are shown in chemical formula 1 to chemical formula 3.

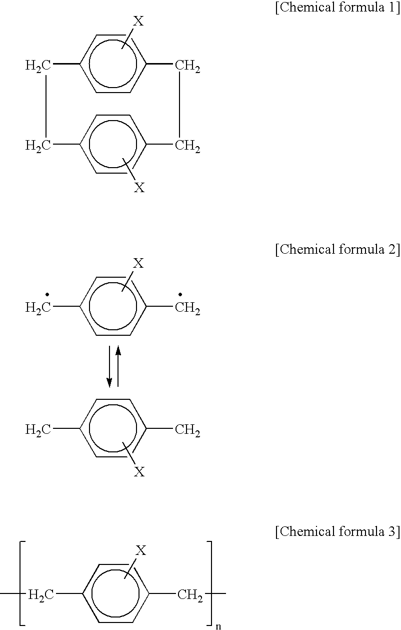

Chemical formula 1 shows a Parylene dimer, chemical formula 2 shows a Parylene monomer, and chemical formula 3 shows a Parylene polymer.

Such Parylene polymers have photo transmittance of above 95%. As shown in Table 1 and Table 2, Parylene polymers have merits of very low gas permeability and moisture vapor permeability.

TABLE 1
Gas permeability (25° C.) (cm³ · mil)/(100 ln²/d · atm)

| Polymer | N2 | O2 | CO2 | H2 |
|---|---|---|---|---|
| Parylene N | 7.7 | 39 | 214 | 540 |
| Parylene.C | 1.0 | 7.2 | 7.7 | 110 |
| Parylene D | 4.5 | 32 | 13 | 240 |
| Epoxide | 4 | 5-10 | 8 | 110 |
| Silicone | — | 50000 | 300000 | 45000 |
| Urethane | 80 | 200 | 3000 | — |

TABLE 2
Moisture Vapor permeability (relative humidity 90%, 37° C.)
(g · mil)/(100 ln²/d)

| | |
|---|---|
| Parylene N | 1.5 |
| Parylene C | 0.21 |
| Parylene D | 0.25 |
| Epoxide | 1.79-2.38 |
| Silicone | 4.4-7.9 |
| Urethane | 2.4-8.7 |

Here Parylene N is a Parylene having H as a substituent of its benzene ring. Parylene C is a Parylene having a Cl as a substituent of its benzene ring. Parylene D is a Parylene having two Cl as substituents of its benzene ring. Chemical formula 4 to chemical formula 6 below show Parylene N, Parylene C, and Parylene D respectively.

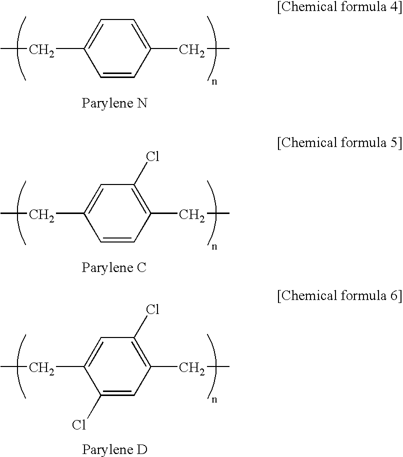

Since Parylene N has a very low dielectric constant and a very high dielectric strength, Parylene N fits as an insulating layer. Also the dielectric constant Parylene N is very stable with respect to the temperature. Since Parylene films are not harmful to humans, Parylene well fits for coatings medical instruments. Parylene C has very low permeability of moisture and corrosive gases and also has very good electrical and mechanical properties. Since Parylene C can be uniformly coated without pin holes, Parylene C well fits for a coated layer requiring resistance against corrosion and chemicals. Parylene D also well fits for a coated layer requiring endurance in high temperature.

Parylene polymers have great coating uniformities and coating thickness of Parylene polymers can be controlled from 1000 Å to a few um. As shown in Table 3, Parylene polymers have excellent properties as an insulating layer due to their very low dielectric constants.

TABLE 3

| Charac- | Paryl- | Paryl- | Paryl- | | | |
|---|---|---|---|---|---|---|
| teristic | ene N | ene C | ene D | Epoxide | Silicone | Urethane |
| Dielectric | 7000 | 5600 | 5500 | — | — | — |
| Strength | | | | | | |
| Dielectric | 2.65 | 3.15 | 2.84 | 3.5-5.0 | 2.7-3.1 | 5.3-7.8 |
| Constant | | | | | | |
| (60 Hz) | | | | | | |

When Parylene is polymerized, Parylene polymer is not resolved by any existing organic solvent and has good chemical resistance.

Since Parylene polymers can be deposited in a room temperature, Parylene polymers do not induce a heat stress. Since Parylene polymers are dry coated without using solvent, Parylene polymers are environmentally friendly. Since Parylene polymers do not use any additive, they do not generate gases. Accordingly, Parylene polymers well fit for manufacturing a thin film transistor array panel specially using silicon. When Parylene polymers are used, manufacturing processes are simplified. Accordingly, manufacturing cost can be decreased.

A data line 171 and a drain electrode 175 are formed on the gate insulating layer 140.

The data line 171 is mainly extending in a longitudinal direction. The data line 171 intersects the gate line 121 and transmits an image signal. A plurality of branches extended from each data line 171 toward the drain electrodes 175 form source electrodes 173. A pair of the source electrode 173 and the drain electrode 175 are separated from each other and located on both sides with respect to a gate electrode 124. The drain electrode 175 has an enlarged portion 176 overlapping a pixel electrode 190 which will be described later. The gate electrode 124, the source electrode 173, and the drain electrode 175 form a thin film transistor (TFT) along with a channel region 154 of a semiconductor layer 150 which will be described later. A channel of the thin film transistor is formed on the channel region 154 interposed between the source electrode 173 and the drain electrode 175.

The width of the one end 179 of the data line 171 is enlarged for contacting with and receiving an image signal from an external circuit.

Also the data line 171 and the drain electrode 175 include a conductive layer made of silver (Ag) series or aluminum (Al) series. The data line 171 and the drain electrode 175 may have multi-layered structures further including other conductive layers made of other materials such as chrome (Cr), titanium (Ti), tantalum (Ta), molybdenum (Mo), and their alloys.

The edge surfaces of the data lines 121 and the drain electrodes 175 are tapered, and the inclination angle of the edge surfaces with respect to a surface of the substrate 110 is in a range of about 30-80 degrees.

A semiconductor layer 150 covering an exposed portion of the gate insulating layer 140 interposed between the source electrode 173 and the drain electrode 175, the source electrode 173, and the drain electrode 175 is formed.

The semiconductor layer 150′ may be made of a silicon semiconductor or an organic semiconductor.

When the semiconductor is made of a silicon semiconductor layer 150, the semiconductor is made of a hydrogenated a-Si (a-Si as the abbreviation for amorphous silicon). A plurality of ohmic contact stripes and ohmic contact islands made of a heavily doped n+ hydrogenated a-Si or a silicide are formed on the upper surface of the hydrogenated a-Si.

On the other hand, an organic semiconductor layer 150 may be made of a derivative including substituents one of tetracene and pentacene or oligothiophene having four to eight thiophene ring which are connected through 2, 5 position.

The organic semiconductor layer 150 may be made of a perylenetetracarboxylic dianhydride (PTCDA), an imide derivative of PTCDA, a napthalenetetracarboxylic dianhydride (NTCDA), or an imide derivative of NTCDA.

The organic semiconductor layer 150 may be made of a metallized pthalocyanine, a halide of it, or a derivative including perylene, coroene, or substituents of perylene and coroene. Here a metal material added to the metallized pthalocynine may be copper (Cu), cobalt (Co), or zinc (Zn).

Also the organic semiconductor layer 150 may be made of co-oligomer or co-polymer of thienylene and vinylene. The organic semiconductor layer 150 may be made of thiophene.

The organic semiconductor layer 150 may be made of perylene, coroene, or a derivative including substituents of them.

Also the organic semiconductor layer 150 may be made of a derivative that includes aromatic or heteroaromatic ring and more than one hydrocarbon chain containing one carbon to thirty carbones.

A passivation layer 180 covers the semiconductor layer 150, the source electrode 173, the drain electrode 175, and the gate insulating layer 140. A contact hole 183 exposing an enlarged portion 176, namely a portion of the drain electrode 176, is formed on the passivation layer 180. The passivation layer 180 may be made of Parylene.

A pixel electrode 190 connected to the drain electrode 175 through the contact hole 183 is formed on the passivation layer 180.

A manufacturing method of a thin film transistor array panel according to an embodiment of the present invention will be described in detail.

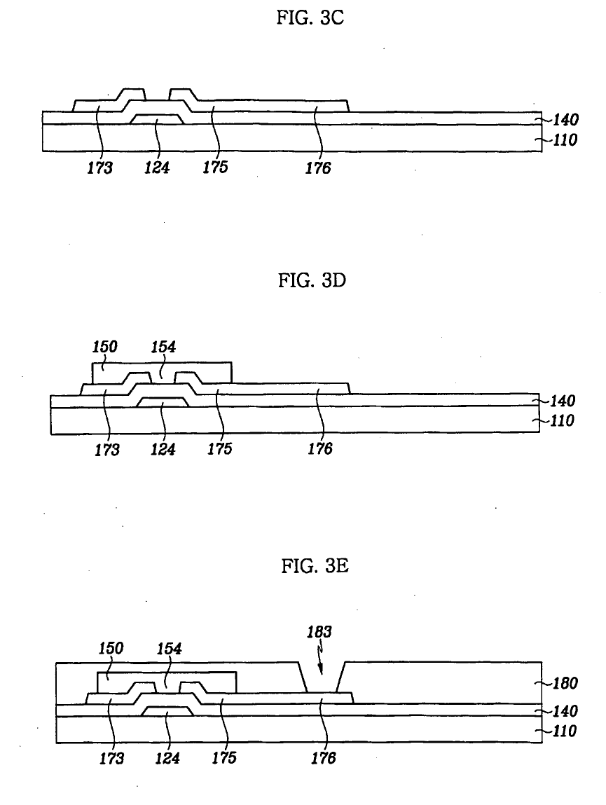

FIGS. 3A to 3E are sectional views illustrating sequential steps of a manufacturing method of a first embodiment of the present invention.

First, as shown in FIG. 3A, a gate electrode 124 is formed on a substrate 110. Here the transparent insulating substrate 110 may be made of glass, silicon, or plastic. The gate electrode 124 is formed on the insulating substrate 110 by photolithographical patterning of a conductive layer such as gold (Au) deposited on the insulating substrate 110.

Next, as shown is FIG. 3B, a gate insulating layer 140 is formed on the substrate 110 and the gate electrode 124. The gate insulating layer 140 is formed by chemical vapor deposition (CVD) of Parylene.

That is to say, Parylene dimers are sublimated in a sublimation part to be dimer gas by increasing temperature. (Vaporization)

The vaporized dimers are decomposed to become monomers while penetrating a heat decomposition region which has a high temperature. (Pyrolysis)

The monomer gas flows to a deposition part of the chemical vapor deposition device and the monomers are polymerized on the surface of the substrate for deposition. (Polymerization)

The conventional method where the gate insulating layer 140 is formed by chemical vapor deposition of a nitride film (SiNx) is performed in a temperature about 150° C. Such a high temperature induces stress to the gate insulating layer to be unfastened from the plastic substrate.

To prevent the unfastening problem, a trial of using an organic gate insulating layer was performed. However, since most of the organic insulating layers are formed by spin coating, it needs a curing process that is performed in a temperature above 200° C. and takes curing time more than one hour. This curing process induces heavy bending of the plastic substrate and damage to the functional adhesive which is disposed on a lower side of the plastic substrate.

In the present invention, since a gate insulating layer 140 is formed by chemical vapor deposition of Parylene in a room temperature, the stress between the substrate 110 and the gate insulating layer 140 is not induced and the lower adhesive does not have damage.

Subsequently, as shown in FIG. 3C, a source electrode 173, a drain electrode 175, and an enlarged portion 176 of the drain electrode 175 are formed on the gate insulating layer 140. They are formed by photo-etching of a conductive layer such as gold (Au) formed by vacuum heat deposition.

Next, as shown in FIG. 3D, a semiconductor layer 150 covering an exposed portion of the gate insulating layer 140 interposed between the source electrode 173 and the drain electrode 175, the source electrode 173, and the drain electrode 175 is formed. The semiconductor layer 150 may be made of a silicon semiconductor or an organic semiconductor.

Subsequently, as shown in FIG. 3E, a passivation layer 180 covering the semiconductor layer 150, the source electrode 173, the drain electrode 175, and the gate insulating layer 140 is formed, and a contact hole 183 is formed to expose the enlarged portion 176 of the drain electrode 175 by photo-etching.

Next, as shown in FIG. 2, a pixel electrode 190 is formed on the passivation layer 180 to contact the enlarged portion 176 through the contact hole 183.

Conventionally, when a semiconductor layer is made of an organic semiconductor such as Pentacene, the passivation layer is formed of an organic insulating layer. However, in such a case, a solvent may permeate to the semiconductor layer and the passivation layer may have cracks on the passivation layer while curing.

However, since a passivation layer made of Parylene according to a first embodiment of the present invention is formed without a heat curing, permeation of solvent and cracks induced by heat contraction are prevented

Since substituent disposed on a phenyl ring of Parylene can easily be changed, a molecule having a molecular alignment fitting for an organic semiconductor can be formed.

Since the passivation layer is made of an organic insulating layer having a low dielectric constant, a thin film transistor array panel having high aperture ratio can be manufactured.

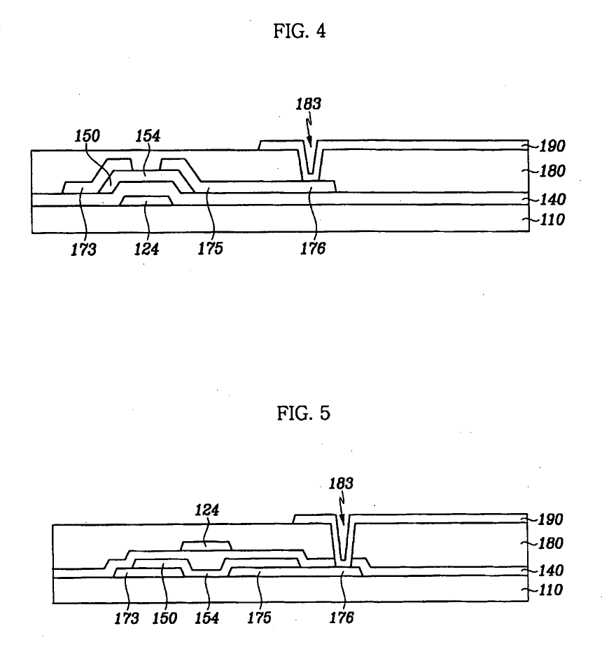

FIG. 1 and FIG. 4 show a thin film transistor array panel according to a second embodiment of the present invention. In FIG. 1 and FIG. 4, the same reference numeral represents the same element having the same functions.

FIG. 1 is a layout view of a thin film transistor array panel according to a first to third embodiment of the present invention, and FIG. 4 is a sectional view of the thin film transistor array panel according to a second embodiment of the present invention shown in FIG. 1 taken along the line II-II′.

As shown in FIG. 1 and FIG. 4, metal wiring paths of gate lines 121, 124, and 129 are formed on a substrate 110 in a thin film transistor array panel according to a second embodiment of the present invention. The substrate 110 may be made of plastic, glass, or metal. A thin film transistor array panel according to the second embodiment of the present invention will be described on the basis of a plastic substrate.

A gate line 121 transmitting a gate signal is extending in a traverse direction. A plurality of gate electrodes 124 consist of upward or downward salient portions of the gate line 121. The width of the one end 129 of the gate line 121 is enlarged for contacting with and receiving a scanning signal from an external circuit.

The gate line 121 includes a conductive layer made of silver (Ag) series such as silver or silver alloys or aluminum (Al) series such as aluminum or aluminum alloys. The gate line 121 may have a multi-layer structure further including other conductive layers made of other materials specially such as chrome (Cr), titanium (Ti), tantalum (Ta), molybdenum (Mo), and their alloys (for example molybdenum-tungsten (MoW) alloys) having a good physical, chemical, and electric contact properties with indium tin oxide (ITO) or indium zinc oxide (IZO). A good combination of a lower layer and an upper layer is chrome/aluminum-neodymium (Cr/AlNd) alloys.

The edge surfaces of the gate lines 121 are tapered, and the inclination angle of the edge surfaces with respect to a surface of the substrate 110 is in a range of about 30-80 degrees.

A gate insulating layer 140 made of Parylene is formed on the gate line 121.

Parylene as the abbreviation for poly-para-xylylene are polymers formed by chemical vapor deposition (CVD) in a vacuum.

A semiconductor layer 150 is formed on the gate insulating layer 140 to correspond the gate electrode 124.

The semiconductor layer 150 may be made of a silicon semiconductor or an organic semiconductor.

When the semiconductor is made of a silicon semiconductor layer 150, the semiconductor is made of a hydrogenated a-Si (a-Si as the abbreviation for amorphous silicon). A plurality of ohmic contact stripes and ohmic contact islands made of a heavily doped n+ hydrogenated a-Si or a silicide are formed on the upper surface of the hydrogenated a-Si.

On the other hand, an organic semiconductor layer 150 may be made of a derivative including substituents one of tetracene and pentacene or oligothiophene having four to eight thiophene ring which are connected through 2, 5 position.

The organic semiconductor layer 150 may be made of a perylenetetracarboxylic dianhydride (PTCDA), an imide derivative of PTCDA, a napthalenetetracarboxylic dianhydride (NTCDA), or an imide derivative of NTCDA.

The organic semiconductor layer 150 may be made of a metallized pthalocyanine, a halide of it, or a derivative including perylene, coroene, or substituents of perylene and coroene. Here a metal material added to the metallized pthalocynine may be copper (Cu), cobalt (Co), or zinc (Zn).

Also the organic semiconductor layer 150 may be made of co-oligomer or co-polymer of thienylene and vinylene. The organic semiconductor layer 150 may be made of thiophene.

The organic semiconductor layer 150 may be made of perylene, coroene, or a derivative including substituents of them.

Also the organic semiconductor layer 150 may be made of a derivative that includes aromatic or heteroaromatic ring and more than one hydrocarbon chain containing one carbon to thirty carbones.

A data line 171 and a drain electrode 175 are formed on a portion of the semiconductor layer 150 and the gate insulating layer 140 to contact with the portion of the semiconductor layer 150.

The data line 171 is mainly extending in a longitudinal direction. The data line 171 intersects the gate line 121 and transmits an image signal. A plurality of branches extended from each data line 171 toward the drain electrodes 175 form source electrodes 173. A pair of the source electrode 173 and the drain electrode 175 are separated from each other and located on both sides with respect to a gate electrode 124. The drain electrode 175 has an enlarged portion 176 overlapping a pixel electrode 190 which will be described later. A gate electrode 124, the source electrode 173, and the drain electrode 175 form a thin film transistor (TFT) along with a channel region 154 of a semiconductor layer 150 which will be described later. A channel of the thin film transistor is formed on the channel region 154 interposed between the source electrode 173 and the drain electrode 175.

The width of the one end 179 of the data line 171 is enlarged for contacting with and receiving an image signal from an external circuit.

Also the data line 171 and the drain electrode 175 include a conductive layer made of silver (Ag) series or aluminum (Al) series. The data line 171 and the drain electrode 175 may have multi-layered structures further including other conductive layers made of other materials such as chrome (Cr), titanium (Ti), tantalum (Ta), molybdenum (Mo), and their alloys.

The edge surfaces of the data lines 121 and the drain electrodes 175 are tapered, and the inclination angle of the edge surfaces with respect to a surface of the substrate 110 is in a range of about 30-80 degrees.

A passivation layer 180 covers the semiconductor layer 150, the source electrode 173, the drain electrode 175, and the gate insulating layer 140. A contact hole 183 exposing an enlarged portion 176, namely the enlarged portion 176 of the drain electrode 175, is formed in the passivation layer 180. The passivation layer 180 may be made of Parylene.

A pixel electrode 190 connected to the drain electrode 175 through the contact hole 183 is formed on the passivation layer 180.

FIG. 1 and FIG. 5 show a thin film transistor array panel according to a third embodiment of the present invention. In FIG. 1 and FIG. 5, the same reference numeral represents the same element having the same functions.

FIG. 1 is a layout view of a thin film transistor array panel according to a first to third embodiment of the present invention, and FIG. 5 is a sectional view of the thin film diode array panel according to a third embodiment of the present invention shown in FIG. 1 taken along the line II-II′.

As shown in FIG. 1 and FIG. 5, in the thin film transistor array panel according to a third embodiment of the present invention, a data line 171 and a drain electrode 175 are formed on an insulating substrate 110. The thin film transistor array panel according to a first embodiment of the present invention will be described on the basis of a plastic substrate.

The data line 171 is mainly extending in a longitudinal direction. The data line 171 intersects a gate line 121 which will be described later and transmits an image signal. A plurality of branches extended from each data line 171 toward the drain electrodes 175 form source electrodes 173. A pair of the source electrode 173 and the drain electrode 175 are separated from each other and located on both sides with respect to a gate electrode 124 which will be described later. The drain electrode 175 has an enlarged portion 176 overlapping a pixel electrode 190 which will be described later. The gate electrode 124, the source electrode 173, and the drain electrode 175 form a thin film transistor (TFT) along with a channel region 154 of a semiconductor layer 150 which will be described later. A channel of the thin film transistor is formed on the channel region 154 interposed between the source electrode 173 and the drain electrode 175.

The width of the one end 179 of the data line 171 is enlarged for contacting with and receiving an image signal from an external circuit.

Also the data line 171 and the drain electrode 175 include a conductive layer made of silver (Ag) series or aluminum (Al) series. The data line 171 and the drain electrode 175 may have multi-layered structures further including other conductive layers made of other materials such as chrome (Cr), titanium (Ti), tantalum (Ta), molybdenum (Mo), and their alloys.

The edge surfaces of the data lines 121 and the drain electrodes 175 are tapered, and the inclination angle of the edge surfaces with respect to a surface of the substrate 110 is in a range of about 30-80 degrees.

A semiconductor layer 150 is formed on the source electrode 173, the drain electrode 175, and an exposed portion of the substrate 110 interposed between the source electrode 173 and the drain electrode 175.

The semiconductor layer 150 may be made of a silicon semiconductor or an organic semiconductor.

When the semiconductor is made of a silicon semiconductor layer 150, the semiconductor is made of a hydrogenated a-Si (a-Si as the abbreviation for amorphous silicon). A plurality of ohmic contact stripes and ohmic contact islands made of a heavily doped n+ hydrogenated a-Si or a silicide are formed on the upper surface of the hydrogenated a-Si.

On the other hand, an organic semiconductor layer 150 may be made of a derivative including substituents one of tetracene and pentacene or oligothiophene having four to eight thiophene ring which are connected through 2, 5 position.

The organic semiconductor layer 150 may be made of a perylenetetracarboxylic dianhydride (PTCDA), an imide derivative of PTCDA, a napthalenetetracarboxylic dianhydride (NTCDA), or an imide derivative of NTCDA.

The organic semiconductor layer 150 may be made of a metallized pthalocyanine, a halide of it, or a derivative including perylene, coroene, or substituents of perylene and coroene. Here a metal material added to the metallized pthalocynine may be copper. (Cu), cobalt (Co), or zinc (Zn).

Also the organic semiconductor layer 150 may be made of co-oligomer or co-polymer of thienylene and vinylene. The organic semiconductor layer 150 may be made of thiophene.

The organic semiconductor layer 150 may be made of perylene, coroene, or a derivative including substituents of them.

Also the organic semiconductor layer 150 may be made of a derivative that includes aromatic or heteroaromatic ring and more than one hydrocarbon chain containing one carbon to thirty carbones.

A gate insulating layer 140 made of Parylene is formed on the substrate 110, the source electrode 173, the drain electrode 175, and the semiconductor layer 150.

Parylene as the abbreviation for poly-para-xylylene are polymers formed by chemical vapor deposition (CVD) in a vacuum.

The gate lines 121, 124, and 129 are formed on the gate insulating layer 140.

A gate line 121 transmitting a gate signal is extending in a traverse direction. A plurality of gate electrodes 124 consist of upward or downward salient portions of the gate line 121. The width of the one end 129 of the gate line 121 is enlarged for contacting with and receiving a scanning signal from an external circuit.

The gate line 121 includes a conductive layer made of silver (Ag) series such as silver or silver alloys or aluminum (Al) series such as aluminum or aluminum alloys. The gate line 121 may have a multi-layer structure further including other conductive layers made of other materials specially such as chrome (Cr), titanium (Ti), tantalum (Ta), molybdenum (Mo), and their alloys (for example molybdenum-tungsten (MoW) alloys) having a good physical, chemical, and electric contact properties with indium tin oxide (ITO) or indium zinc oxide (IZO). A good combination of a lower layer and an upper layer is chrome/aluminum-neodymium (Cr/AlNd) alloys.

The edge surfaces of the gate lines 121 are tapered, and the inclination angle of the edge surfaces with respect to a surface of the substrate 110 is in a range of about 30-80 degrees.

A passivation layer 180 covers the semiconductor layer 150, the source electrode 173, the drain electrode 175, and the gate insulating layer 140. A contact hole 183 exposing an enlarged portion 176, namely the enlarged portion 176 of the drain electrode 175, is formed in the passivation layer 180. The passivation layer 180 may be made of Parylene.

A pixel electrode 190 connected to the drain electrode 175 through the contact hole 183 is formed on the passivation layer 180.

In the present invention, since a gate insulating layer 140 is formed by chemical vapor deposition of Parylene in a room temperature, the stress between the substrate 110 and the gate insulating layer 140 is not induced and the lower adhesive does not have damage.

In addition, since a passivation layer made of Parylene according to the present invention is formed without a heat curing, permeation of solvent and cracks induced by heat contraction are prevented

Although the illustrative embodiments have been described herein with reference to the accompanying drawings, it is to be understood that the present invention is not limited to those precise embodiments, and that various changes and modifications may be affected therein by one of ordinary skill in the related art without departing from the scope or spirit of the invention. All such changes and modifications are intended to be included within the scope of the invention as defined by the appended claims.

1. A thin film transistor array panel comprising:
a substrate;
a gate electrode formed on the substrate;
a gate insulating layer covering the gate electrode and the substrate;
a source electrode and a drain electrode formed on the gate insulating layer;
an organic semiconductor layer formed on the gate insulating layer and the source electrode and the drain electrode; and
a passivation layer covering the semiconductor layer, the source electrode, the drain electrode, and the gate insulating layer,
wherein at least one of the gate insulating layer and the passivation layer is made of Parylene.

2. The thin film transistor array panel of claim 1, wherein the substrate is made of one material selected from plastic, glass, and metal.

3. (canceled)

4. The thin film transistor array panel of claim 1 further comprising a pixel electrode formed on the passivation layer and connected to the drain electrode through a contact hole of the passivation layer that exposes a portion of the drain electrode.

5. A manufacturing method of a thin film transistor array panel comprising:
forming a gate electrode on a substrate;
forming a gate insulating layer covering the gate electrode on the substrate;
forming a source electrode and a drain electrode on the gate insulating layer;
forming an organic semiconductor layer covering the source electrode and a portion of the drain electrode; and
forming a passivation layer covering the gate insulating layer, the source electrode, the drain electrode, and the organic semiconductor layer,
wherein at least one of the gate insulating layer and the passivation layer is made of Parylene.

6. The manufacturing method of a thin film transistor of claim 5, wherein the gate insulating layer or the passivation layer is made of Parylene by chemical vapor deposition.

7. A thin film transistor comprising:
a substrate;
a gate electrode formed on the substrate;
a gate insulating layer covering the substrate and the gate electrode;
an organic semiconductor layer formed on the gate insulating layer and disposed on the corresponding portion of the gate electrode;
a source electrode and a drain electrode contacting portions of the organic semiconductor layer, formed on the gate insulating layer, and separated by a predetermined distance; and
a passivation layer covering the organic semiconductor layer, the gate insulating layer, the source electrode, and the drain electrode,
wherein at least one of the gate insulating layer and the passivation layer is made of Parylene.

8. A thin film transistor array panel comprising:
a substrate;
a source electrode and a drain electrode formed on the substrate and separated by a predetermined distance;
an organic semiconductor layer covering the source electrode and the drain electrode;
a gate insulating layer covering the substrate and the organic semiconductor layer;
a gate electrode formed on the gate insulating layer and disposed on the corresponding portion between the source electrode and the drain electrode; and
a passivation layer covering the gate insulating layer and the gate electrode,
wherein at least one of the gate insulating layer and the passivation layer is made of Parylene.

9. The thin film transistor of claim 8 further comprising a pixel electrode formed on the passivation layer and connected to the drain electrode through a contact hole of the gate insulating layer and the passivation layer that exposes a portion of the drain electrode.
